(19) United States
(12) Patent Application Publication
(10) Pub. No.: US 2025/0300105 A1
(43) Pub. Date: Sep. 25, 2025

(54) POWER DEVICES WITH MULTIPLE METAL LAYER THICKNESSES

(71) Applicant: Wolfspeed, Inc., Durham, NC (US)

(72) Inventors: Bradley McGee, Bella Vista, AR (US); Brice McPherson, Springdale, AR (US); Thomas Harrington, Durham, NC (US); Sneha Pandya, Apex, NC (US); Morgan Roddy, Fayetteville, AR (US); Adam Barkley, Raleigh, NC (US); Brandon Passmore, Fayetteville, AR (US)

(21) Appl. No.: 18/612,302

(22) Filed: Mar. 21, 2024

(51) Int. Cl. H01L 23/00

(52) U.S. Cl. CPC H01L 24/05; H01L 24/04; H01L 24/06; H01L 24/37; H01L 24/45; H01L 24/46; H01L 2224/04034; H01L 2224/04042; H01L 2224/05012; H01L 2224/05082; H01L 2224/05124; H01L 2224/05147; H01L 2224/05186; H01L 2224/05547; H01L 2224/05553; H01L 2224/05554; H01L 2224/05555; H01L 2224/05557; H01L 2224/05564; H01L 2224/05639; H01L 2224/05647; H01L 2224/05655; H01L 2224/05664; H01L 2224/06051; H01L 2224/06181; H01L 2224/3702; H01L 2224/4502; H01L 2224/46; H01L 2924/0132; H01L 2924/04941; H01L 2924/13055; H01L 2924/13062; H01L 2924/13091

(57) ABSTRACT

A semiconductor device includes a semiconductor die, and a topside metallization on a first side of the semiconductor die. The topside metallization includes a metal layer on the semiconductor die, the metal layer having a first thickness, and at least two discrete bond pads on the metal layer. The discrete bond pads have a second thickness that is larger than the first thickness. A backside metallization may be formed on the back side of the semiconductor die. The backside metallization includes a metal layer having a first portion having a first thickness and a second portion having a second thickness that is smaller than the first thickness.

### FIELD

The present disclosure relates to semiconductor power devices, and in particular to metallizations for power semiconductor devices.

### BACKGROUND

Power semiconductor devices typically have relatively thin topside and backside metallizations. This is the result of a number of factors, including metal deposition process capabilities, process time and cost, and stress induced warpage of the wafer. For high current power devices, however, these thin metallization layers introduce limitations to performance and reliability of the product. This is particularly so for wide band gap devices which offer considerably higher potential current densities. These higher densities require advancements in the devices and their associated packages to achieve their full potential.

The presence of thin layers may limit performance and reliability at both the device and package levels. For example, at the device level, thin metal layers may result in high current concentrations, uneven current distribution, localized heating and/or localized thermal stresses. At the package level, thin metal layers may result in limitations in the power interconnection size (wire diameter, ribbon thickness, etc.), limitations in the power interconnection material (softer materials vs. harder materials), a higher risk of device damage during wire/ribbon bonding, localized thermal stresses at the interconnection interface and/or limiting the allowable current (i.e. the device is not fully utilized).

Thicker metallization, particularly on the topside metal layer, may help address these issues on multiple fronts. For example, the use of thicker metallization (particularly top side metallization) may allow buffering the current to a more even distribution, and/or may reduce the localized heating and spreading it away from critical interfaces. Additionally, the use of thicker metallization may help to improve robustness for larger size power interconnections and/or may provide a capability to apply compatible materials for different power interconnection materials.

Creating the thicker metallization on a semiconductor wafer, however, has challenges which limit to what is practical and possible. Wafers are relatively thin at the time of processing, and may encounter multiple high temperature conditions as the devices are formed. Thicker metal layers, particularly if only on one side, can introduce warpage and distortion that are often too high for usage.

### SUMMARY

A semiconductor device according to some embodiments includes a semiconductor die, and a topside metallization on a first side of the semiconductor die. The topside metallization includes a metal layer on the semiconductor die, the metal layer having a first thickness, and at least two discrete bond pads on the metal layer. The discrete bond pads have a second thickness that is larger than the first thickness.

The semiconductor device may further include at least two wires bonded to respective ones of the discrete bond pads. The discrete bond pads may include at least two source bond pads and a kelvin bond pad.

The kelvin bond pad may have a different surface area than the source bond pads. The discrete bond pads may include emitter or anode pads.

The discrete bond pads may be oriented in a staggered or offset pattern on the metal layer. In some embodiments, the discrete bond pads are oriented on the metal layer in a pattern of rows and columns. The discrete bond pads may be oriented on the metal layer in a pattern of diagonals, crosses and/or in a chevron pattern. The discrete bond pads may have a rectangular peripheral shape. The discrete bond pads may have a circular, oval or octagonal peripheral shape.

The semiconductor device may further include a clip interconnect or ribbon connection connected to the at least two discrete bond pads.

The metal layer may include copper. The at least two discrete bond pads may include copper. The at least two discrete bond pads are inset from edges of the metal layer.

The metal layer may include a barrier layer and a capping layer, where the barrier layer is between the semiconductor die and the capping layer. An outer edge of the capping layer is inset from an outer edge of the barrier layer.

The metal layer may include a material that has a mechanical strength that is about the same as a material of the discrete bond pads.

The metal layer and the discrete bond pads may include the same material.

The discrete bond pads may include a material that has a mechanical strength that is great enough to support the formation of wirebonds thereto.

The at least two discrete bond pads may be electrically connected to source, emitter, anode and/or gate contacts of the semiconductor device.

A total surface area of the discrete bond pads may be greater than a surface area of the thin layer.

The thin layer may be non-planar.

The semiconductor device further include a backside metallization on a second side of the semiconductor die opposite the first side. The backside metallization may include a thin metal layer and a thick metal layer on the thin metal layer, wherein at least a portion of the second side of the semiconductor die is free of the thick metal layer so that at least a portion of the thin metal layer is exposed opposite the semiconductor die.

The discrete bond pads may be arranged to reduce stress that would be otherwise be imparted to the semiconductor die if the discrete bond pads were formed as a single unitary bond pad.

A semiconductor device according to some embodiments includes a semiconductor die having a first side and a second side opposite the first side, at least one bond pad on the first side of the semiconductor die, and a backside metallization on the second side of the semiconductor die. The backside metallization includes a metal layer having a first portion having a first thickness and a second portion having a second thickness that is smaller than the first thickness.

The second portion of the metal layer may include a peripheral region surrounding the first portion.

The second portion of the metal layer may include at least two of attachment regions within a periphery of the first portion of the metal layer.

The attachment regions within the periphery of the first portion of the metal layer may include at least two regions near corners of the first portion of the metal layer.

The attachment regions within the periphery of the first portion of the metal layer may include at least two regions near edges of the first portion of the metal layer.

The attachment regions within the periphery of the first portion of the metal layer may include at least two regions arranged in rows and columns.

The attachment regions within the periphery of the first portion of the metal layer may include at least two linear regions.

The attachment regions may include regions having a peripheral shape that is circular, square, triangular, rectangular, L-shaped, linear, octagonal or irregular.

The semiconductor device may further include a topside metallization on the first side of the semiconductor die. The topside metallization may include a first metal layer on the semiconductor die, the first metal layer having a first thickness, and at least two discrete bond pads on the metal layer, wherein the at least two discrete bond pads have a second thickness that is larger than the first thickness.

### BRIEF DESCRIPTION OF THE DRAWINGS

FIG. 1 illustrates an example of a MOSFET device.

FIG. 2 illustrates an example of a MOSFET circuit.

FIGS. 3, 4 and 5 illustrate a cross-sectional views of MOSFET devices including a plurality of MOSFET cells.

FIG. 6 illustrates semiconductor wafers experiencing various forms of warpage.

FIG. 7 illustrates a semiconductor device according to some embodiments.

FIGS. 8A and 8B, 9 and 10 illustrate metal stacks on a semiconductor device according to some embodiments.

FIGS. 11, 12, 13, 14, 15, 16, 17, 18, 19 and 20 depict example topside patterns for wire bonding in devices including a plurality of bond pads according to various embodiments.

FIGS. 21, 22, 23, 24 and 25 illustrate backside metallization patterns according to various embodiments.

FIG. 26 illustrates backside metallization structures according to various embodiments.

FIGS. 27, 28 and 29 illustrate embodiments in which the topside metallization includes diagonalized bond pad arrangements.

### DETAILED DESCRIPTION OF EMBODIMENTS

Wide Band Gap power devices, including devices based on silicon carbide (SIC), gallium nitride (GaN), and the like offer a high level of performance benefits, including high voltage blocking, low on-resistance, high current, fast switching, low switching losses, high junction temperatures, and high thermal conductivity. Ultimately, these characteristics result in a notable increase in potential power density, which is power processed per area or volume.

Achieving this potential, however, requires addressing significant challenges at the package and system level. The higher voltages, currents, and switching speeds manifest into significantly higher physical stresses applied onto smaller and more constrained areas. To fully take advantage of what SiC technology has to offer, several challenges must be addressed both at the device and the package level, including the formation of electrical interconnections from the device topsides to the package substrate or terminals. Other challenges include waste heat removal, including conduction and switching losses from the devices, and effective electrical isolation between high voltage potentials. Wide bandgap power devices should also have the capability to handle high steady state currents, capability to handle high transient current events, mechanical robustness to reliably operate in high stress, high temperature, high vibration environments. Such devices should be compatible with advanced interconnection materials, structures, and techniques, as well as with advanced device attach materials, structures, and techniques.

Power packages contain power semiconductor devices, including metal-oxide semiconductor field effect transistors (MOSFETs), junction field effect transistors (JFETs), insulated gate bipolar transistors (IGBTs), diodes, and the like, arranged into a variety of circuit topologies. A device package serves many functions, including electrical interconnection, electrical isolation, heat transfer, and mechanical structure. The package protects devices from environmental contamination and moisture, and provides external electrical and thermal connection interfaces. The package should also provide compliance with safety standards, such as voltage creepage and clearance distances.

Generally speaking, power packages can be categorized as either a discrete package, housing a single device, or a power module, housing multiple devices. Power modules may place multiple devices in parallel and arrange them into various circuit topologies. As an example, a single switch position package that houses one device would be categorized a discrete, and one that houses multiple devices in parallel (to increase output current) would be considered a power module.

Packages conventionally use, but are not limited to, some combination of the following components, each providing multiple functions. These are summarized in the following table. The terms used in this disclosure, unless otherwise indicated, follow the definitions outlined in Table 1 below.

TABLE 1
Definitions

| Item | Description |
|---|---|
| Power Device(s) | Controllable switches MOSFET, IGBT, and the like and Diodes |
| Substrate, Power | Layered metal and ceramic for high current electrical interconnection, |
| | high voltage isolation, high thermal conductivity, coefficient of thermal |
| | expansion (CTE) matching, and external thermal interface |
| Substrate, Signal | Layered Printed Circuit Board (PCB), layered metal and ceramic, thick |
| | film, and the like for high frequency electrical interconnection and high |
| | voltage isolation |
| Terminal, Power | Metal contact for high current external connection and internal |
| | interconnection |
| Terminal, Signal | Metal contact or connector for high frequency external connection and |
| | internal interconnection |
| Lead Frame | Metal contact strip for high current external connection and internal |
| | interconnection; Contacts are joined together on a single sheet, often |
| | with multiple products per sheet, and are processed as an array and then |
| | formed and singulated |
| Base Plate | Metal or composite material for mechanical structure, high thermal |
| | conductivity, coefficient of thermal expansion (CTE) matching, and |
| | external thermal interface |
| Device Attach | Solder, adhesive, or sintered metal, and the like for mechanical structure, |
| | high current interconnection, and high thermal conductivity |
| Terminal Attach | Solder, adhesive, sintered metal, laser weld, ultrasonic weld, and the like |
| | for mechanical structure, high current interconnection, and high thermal |
| | conductivity |
| Substrate Attach | Solder, adhesive, or sintered metal, and the like for mechanical structure |
| | and high thermal conductivity |
| Interconnection | Conductive element forming an electrical connection between one |
| | electrical node and another |
| Wire Bonds, Power | Ultrasonically or thermosonically bonded large diameter wire, ribbon, |
| | and the like for high current electrical interconnection |
| Wire Bonds, Signal | Ultrasonically or thermosonically bonded small diameter wire, ribbon, |
| | and the like for low current electrical interconnection |
| Case/Housing | Injection molded case and lid, providing mechanical structure, high |
| | voltage isolation, and acting as a well for the encapsulation material |
| Mold Compound | Transfer or compression molded epoxy molding compound (EMC) for |
| | mechanical structure, high voltage isolation, coefficient of thermal |
| | expansion (CTE) matching, and low humidity absorption |
| Encapsulation | Soft, flexible silicone or similar encapsulation material for high voltage |
| | isolation, and low humidity absorption |
| Temperature Sensor | Passive or active element that can be used to monitor internal |
| | temperatures |
| Signal Circuitry | Resistors, capacitors, surface mount components, sensors, and the like |
| | for stabilization of the dynamic switching performance of the devices or |
| | for other internal circuit requirements, such as active miller clamping, |
| | etc. |

Some typical design requirements for power device packages include high power density (small package size), high current, high voltage, high temperature operation, low thermal resistance, low stray inductance, fast and clean switching, high efficiency through low on-resistance, high efficiency through high speed switching, thoughtful external terminal layout for effective interconnection, compliance with creepage and clearance standards, moisture sensitivity level (MSL) compliance, and low cost.

A power semiconductor device is typically vertical, meaning power flows from top the backside to the topside of the chip (or vice versa). While there are many types of power devices where this technique applies, a MOSFET will be used for the purposes of explanation and illustration.

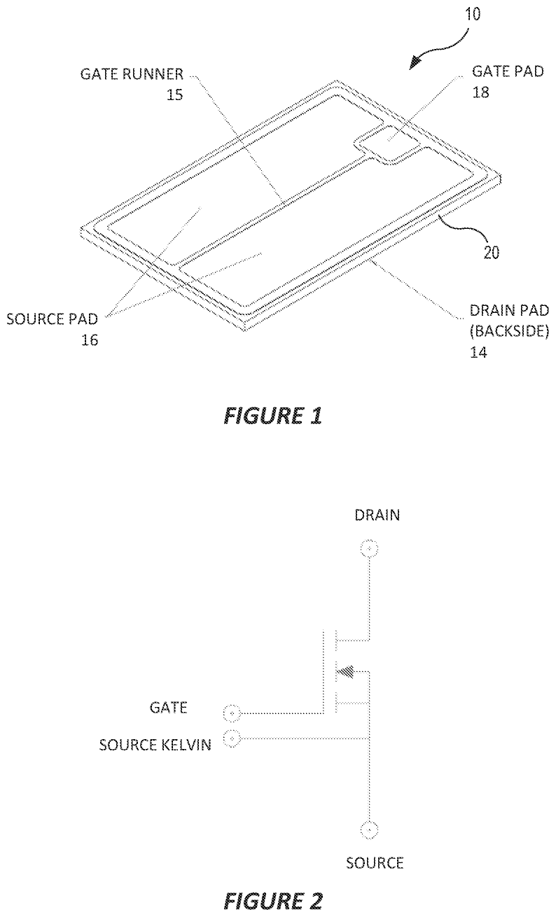

A power MOSFET is a three terminal device: (1) gate, (2) source, and (3) drain. Often an additional kelvin connection to the source terminal is made to optimize switching performance to isolate the power and signal loops. The gate and source are located on what will be referred to as the device topside, while the drain is located on the device backside. The high current path flows from the drain to source or source to drain, through the area of the device. An example MOSFET device is depicted in FIG. 1, and an example MOSFET circuit element is depicted in FIG. 2.

Referring to FIGS. 1 and 2, a MOSFET device 10 generally includes source, gate and drain terminals. The source terminal is connected to a pair of source pads 16 on the front or top side of a semiconductor die 20, and the gate terminal is connected to a gate pad 18 on the front or top side of the die 20. A gate runner 15 extends from the gate pad 18 and distributes the gate signal across the die 20. The drain terminal is connected to a drain pad 14 on the back side of the die 20.

The topside and backside metallizations that form the source pads 16, the gate pad 18 and the drain pad 14 generally include stack of metals to provide a variety of functions, such as ohmic contact, diffusion barrier, seed layers for plating or adhesion, and a capping bonding layer. The topside bonding layer is generally the thickest and is designed to be metallurgically compatible with the desired topside interconnection method. For example, the topside bonding layer may be aluminum to be most compatible with aluminum wire bonding or copper to be compatible with copper wire bonding. The backside metallization is also a stack of metals serving similar functions. Backside attaches tend to be a soldered, brazed, or sintered, rather than connected to wire bonds. The thickness of each layer is generally selected based on what is practical and cost effective to fabricate, what operating conditions are expected, and what performance requirements must be met.

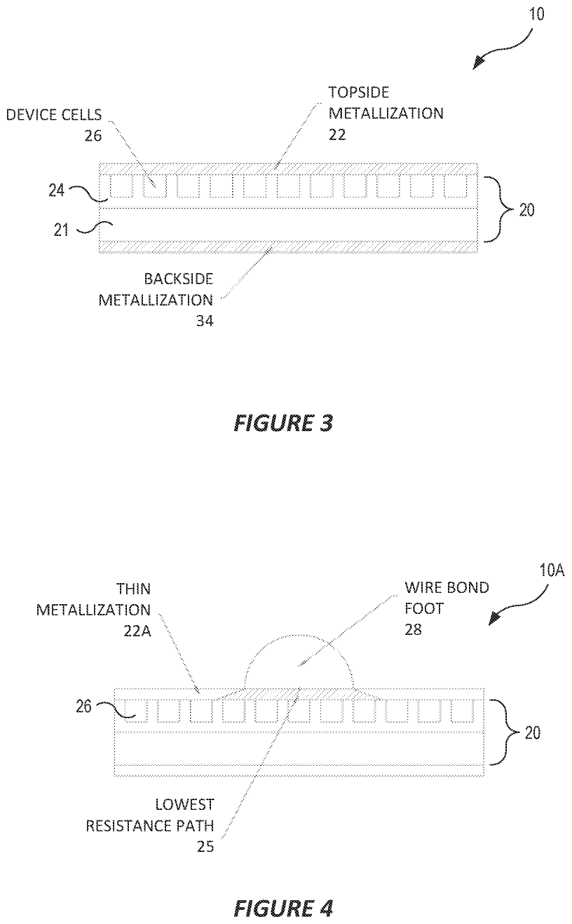

While a power semiconductor device operates as a single device, the physical chip layout is a large array of paralleled device ‘cells’ interconnected through the topside metallization and other functional layers. This is illustrated in FIG. 3 showing a sectional view of a power semiconductor device 10 including a substrate 21 and an epitaxial layer 24 in which a plurality of device cells 26 are formed. The power semiconductor device 10 may be a MOSFET, JFET, IGBT, diode, or other type of power semiconductor device. A backside metallization 34 is formed on the back, or bottom side of the die 20, and a topside metallization 22 is formed on the front, or top side of the die 20.

Note that there are many more features and functional layers than depicted in FIG. 3 for simplicity, and the layers are not to scale to show detail. The device cells 26 are paralleled through the topside metallization 22 providing contact to a source in the case of a MOSFET or JFET, an emitter in the case of an IGBT or an anode in the case of a power diode. The bulk of the semiconductor material is used for voltage isolation, with the backside metallization 34 providing electrical contact to the drain (for a MOSFET or JFET), collector (for an IGBT) or cathode (for a diode). Current flows vertically through the device from the part of the topside metallization 22 to the backside metallization 34.

In many cases, only a portion of the source pad 16 can be used for interconnection through wire bonds or ribbons. Hence, current must spread from these sites out towards the device cells 26. To effectively obtain the most performance out of the device 10, each of these device cells 26 should be fully utilized by carrying as much current as possible. Accordingly, distributing the current from the interconnection sites to each and every cell 26 is important for full device utilization. Distributing current equally among the cells also helps to spread heat evenly across the device.

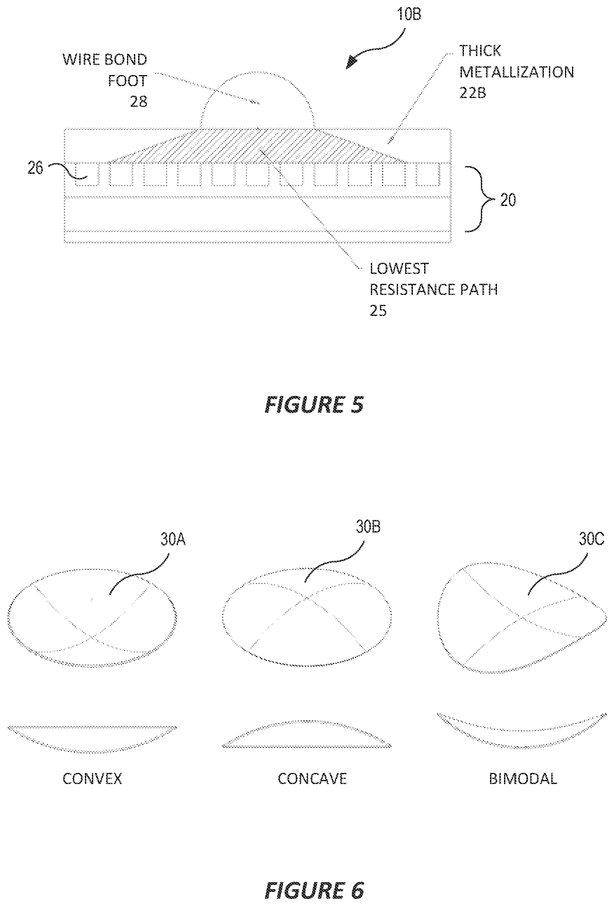

Using thicker metal may reduce the sheet resistance of the topside metallization 22, and may provide more cross sectional area through which current can readily spread. Increasing the thickness of the topside metallization layer 22 may allow for more cells to access a low resistance, efficient path to the input and output sites for current flow. This buffering effect may reduce high current concentrations and/or may reduce localized heating at the bonding interfaces. FIGS. 4 and 5 depict the buffering effect for thin (FIG. 4) topside metallizations 22A and thick (FIG. 5) topside metallizations 22B. Note that the device structure and scale of the image are used for description purposes and are not true to structure or scale for an actual device and package. A wire bond foot 28 is provided on the topside metallizations 22A, 22B, and current from the wire bond foot 28 flows into the die 20 via a lowest resistance path 25.

With a thin metallization 22A, there is limited room to laterally spread current and the resulting heat at the interface. These localized high current and heat densities can act to stress and weaken the interface. A thicker metallization 22B helps to buffer the current and heat to better distribute the energy away from the interfaces and evenly towards the device cells 26.

The application of a thicker topside metal may also improve device robustness for more aggressive interconnection methods. For example, copper wire is substantially harder than aluminum, and could cause damage to the sensitive device during the wire bonding process. Thicker metals can buffer out the energy applied to form the metallurgical bonds, and a ‘cushioning’ effect adding resilience and wider process windows. Thus, it may be preferable for the thicker topside metal 22A, 22B to improve the performance and bondability of copper wires. Moreover, due to the high conductivity of copper, the use of copper in the topside metal 22A, 22B can enable the use of fewer wire bonds, or may allow higher currents for a given number of wire bonds. The use of thick topside metal may also accommodate larger wire bond footprints, which can allow for more current.

While there are numerous benefits to thicker metallization layers, there are also many processing challenges. For example, there is a large coefficient of thermal expansion (CTE) imbalance between the semiconductor wafer and the metal layers. As the wafer experiences exposures to high temperatures during processing, the metal and semiconductor expand and contract at different rates, creating thermal stress. These thermal stresses can manifest as warpage of the wafer once cooled.

Warpage is a major problem which may reduce yield or render the wafer useless for further processing. Various types of warpage of wafers 30 are illustrated in FIG. 6. Depending on the temperature delta, metal layout, wafer thickness and diameter, and other factors, a warped wafer could be convex (30A), concave (30B), or bimodal (30C), as shown in FIG. 6. The risk of warpage exceeding a usable level increases as the metal thickness increases. This is particularly so if it is only increased on one side of the device.

### Selective Topside Metallization

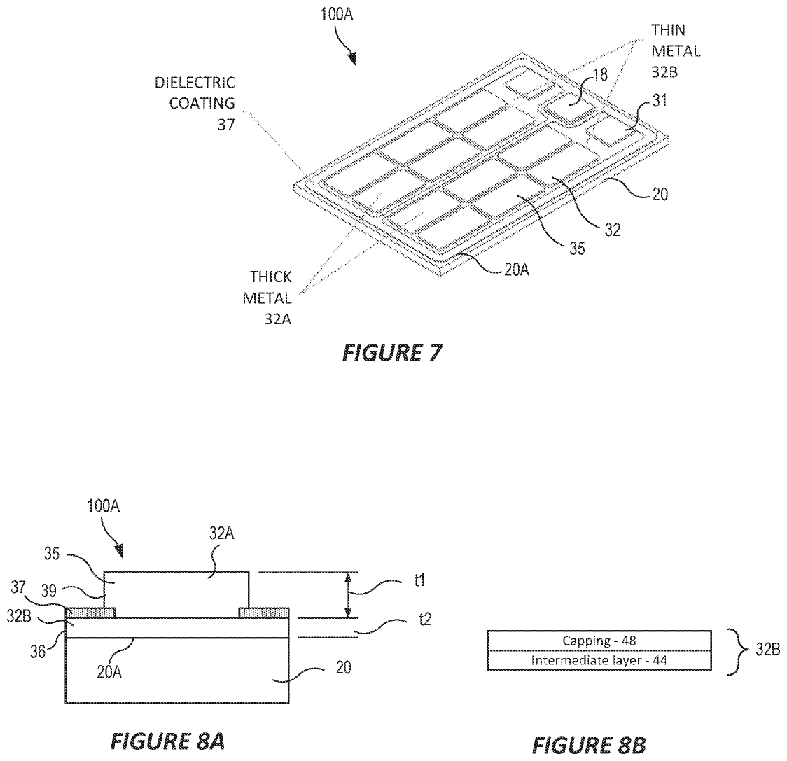

To address the issue of wafer warpage while delivering the benefits of thick metallization, some embodiments apply thick metal selectively using multiple masked deposition processes. That is, instead of applying thick metal on all conductive surfaces, the thick metal is applied selectively only where it is needed. These localized thick plateaus of metal provide buffering and robustness but are small enough that the metal loading is greatly reduced, and the expansion stresses are lessened. This approach is shown on an example power device in FIGS. 7, 8A and 8B. A section view is also presented. Note that there are many functional layers in the sectional view that are not shown for simplicity. Embodiments are described herein in the context of MOSFET power semiconductor devices. However, it will be appreciated that the inventive concepts may be applied to many different types of semiconductor devices, such as JFETs, IGBTs, diodes, and other devices.

Referring to FIGS. 7, 8A and 8B, a semiconductor MOSFET device 100A according to some embodiments includes a semiconductor die 20 on which a topside metallization 32 is formed on an upper surface 20A of the semiconductor die 20. The top side metallization 32 includes a thin metal layer 32B formed on an upper surface 20A of the die 20, and a thick metal layer 32A formed on the thin metal layer 32B. The thin metal layer 32B and the thick metal layer 32A may together form, for example, a source contact of the semiconductor device 100A. As used herein in reference to metal layers, the terms “thick” and “thin” refer to the dimension of the metal layer as measured in a direction normal to the surface on which the metal layer is formed, such as the upper surface 20A of the semiconductor die 20. Thus, for example, the thick metal layer 32A has a thickness t1, while the thin metal layer 32B has a thickness t2 as illustrated in FIG. 8A.

Referring still to FIGS. 7, 8A and 8B, a dielectric coating 37 may be formed on portions of the upper surface 20A of the die 20 not covered by the thick metal layer 32A. The thick metal layer 32A may include a metal, such as copper or aluminum, that is suitable for connection by a wire bond (not shown). The thick metal layer 32B is formed as a plurality of discrete thick metal regions on the thin metal layer 32A. The discrete thick metal regions may serve as bond pads 35 of the device 100A. That is, the bond pads 35 are physically separated from one another and are mechanically and electrically connected to one another only through the thin metal layer 32B. The bond pads 35 include a plurality of source wire bond pads, or source bond pads. The bond pads 35 also include a source kelvin bond pad 31 to facilitate a source kelvin connection to the device input signal line as shown in FIG. 2.

The thick metal layer 32A is formed where needed for a desired performance, interconnection scheme, and interconnection material. It may be deposited through similar processes as the thin metal layer 32B. A mask or similar may be used to only apply the metal where desired to form the bond pads 35. The bond pads 35 may also be formed by plating a thick layer of metal over the thin metal layer 32B and etching or selectively depositing the plated metal to form the bond pads 35. Plating is a practical and cost effective to form relatively thick layers.

The thin metal layer 32B may have a thickness of about 1 micron to 5 microns, while the thick metal layer 32A may have a thickness of about 20 microns or more. In some embodiments, the thick metal layer 32A may have a thickness that is at least 1.5 times the thickness of the thin metal layer. In further embodiments, the thick metal layer 32A may have a thickness that is at least 2 times the thickness of the thin metal layer. In still further embodiments, the thick metal layer 32A may have a thickness that is at least 5 times the thickness of the thin metal layer. In still further embodiments, the thick metal layer 32A may have a thickness that is at least 10 times the thickness of the thin metal layer. In still further embodiments, the thick metal layer 32A may have a thickness that is at least 20 times the thickness of the thin metal layer.

By forming a thin layer of metal on the semiconductor die 20, the design rule for manufacturing the semiconductor die 20 may be tightened, which means that it maybe possible to form smaller or more dense features in the semiconductor die 20 than would be possible if only a single thick metal stack were formed thereon. It will be appreciated that the design rule for a semiconductor die determines how closely or densely features can be formed on the die. When the initial metal layer on the die is thick, a larger design rule is required due to lateral variations in the thick metal layer to discourage the initial metal layer from undesirably contacting unintended features on the die. According to some embodiments, by forming an initial metal layer as a thin layer 32B having a thickness of less than 5 microns, the design rule for the semiconductor die may be reduced.

As seen in FIG. 8A, the thick metal layer 32A may be formed so that the side walls of the bond pads 35 are inwardly recessed from the sidewalls of the thin metal layer 32B. That is, the outside edges 39 of the bond pads 35 may not reach all the way to the outside edges 36 of the thin metal layer 32B. As used herein with respect to metal layers, the term “edge” refers to the outer sidewall, outer surface or outer portion of the metal layer.

Referring to FIG. 8B, the thin metal layer 32B may be part of a first layer metal stack which typically includes a capping metal 48 and one or more intermediate layers 44 between the capping layer 48 and the semiconductor die 20. These layers may be deposited through a number of processes, including but not limited to evaporation, sputtering, plating, and the like.

The capping layer 48 may be a metal that is metallurgically compatible with the desired material for the thick metal layer 32A, which typically includes copper but may include aluminum. For example, the capping layer 48 may include copper, aluminum copper, aluminum, or any other suitable metal.

The thick metal layer 32A may include a material with a high mechanical strength. Generally, copper may be desirable to use for the thick metal layer 32A, due to its mechanical strength and/or hardness, to support the formation of copper wire bonds to the bond pads 35. The force of forming a wire bond to the bond pad 35 may displace softer metals, such as aluminum, pushing it to undesired locations on the die.

Copper is also desirable for use as the thick metal layer 32A due to its high electrical and thermal conductivity. However, in some cases other metals may be desirable. The thick metal layer 32A may be left bare, or in some cases it may be further plated with a more oxidation resistant material such as nickel, palladium, gold, etc.

The intermediate layer 44 may include a diffusion barrier layer which serves the purpose of obstructing inter-diffusion of soluble metals. As an example, if the capping layer 48 contains copper, then without a diffusion barrier, copper may spread into and contaminate the underlying metals and also likely diffuse into the underlying insulating layers, interconnects, gate oxides, and substrate of the die 20. This ultimately may inhibit or destroy the function of the device 100A. Adding an insoluble diffusion barrier layer of, for example, TiN may obstruct this from occurring. The intermediate layer may include other layers, such as adhesion layers, seed layers, etc.

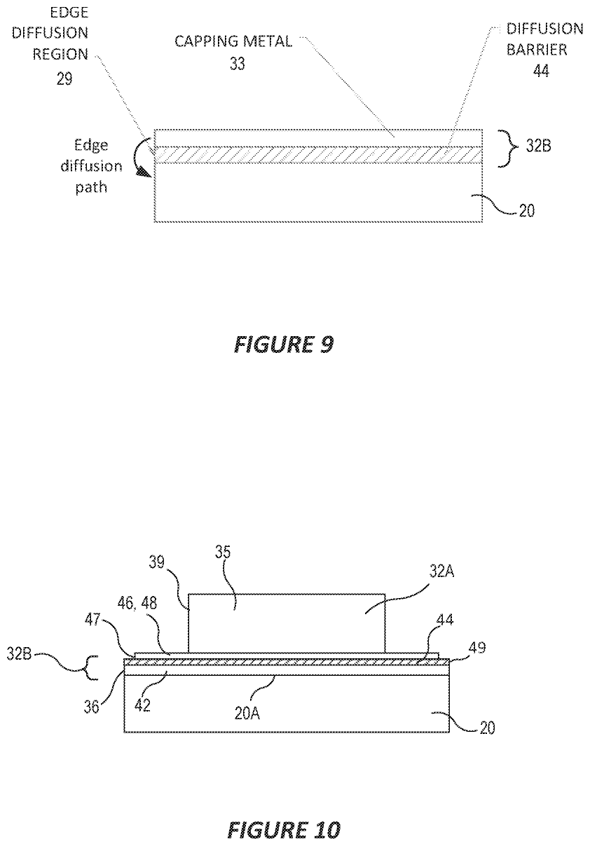

Even if a diffusion barrier is used, however, diffusion may still be possible at the edges of the interface. That is, metal can diffuse around the edges where there is no diffusion barrier in the vertical direction. This is illustrated in FIG. 9, which shows a capping layer with regions 29 where edge diffusion could occur (left) from a capping layer 33 to the die 20.

FIG. 10 illustrates a selective approach in which the seed layer 46 and capping layer 48 are inset from the edges of the diffusion barrier layer 44. That is, edges 47 of the seed layer 46 and capping layer 48 do not extend all the way to the edge 49 of the diffusion barrier layer 44. This may reduce the possibility of edge diffusion from the seed and copper layers 46, 48 into the die 20.

Moreover, the bond pad 35 of the thick metal layer 32A is inset such that the edge 49 diffusion barrier layer 44 extends past the edge 39 of the bond pad 35 to further reduce the possibility of edge diffusion from the bond pad 35.

### Topside Embodiments

There are many implementations of topside metallization using the selective metal approach according to various embodiments of the inventive concepts. The specific approach could be tailored to accommodate a number of factors, including one or more of device size, device aspect ratio, device shape, pad size, interconnection method, interconnection material, bonding direction, bonding pattern, package features and/or product application.

Example topside features are described in the following for a reference device. These may be used by themselves or in combination with backside features depending on many of the factors listed above. Interconnection in the examples includes signal and power bonds. Individual interconnection bonds for each thick pad are illustrated. However, the pads may be stitch bonded together as well, which is not pictured but is also possible with this method.

Note that a specific implementation is not limited to these examples, and ultimately is driven by product and application factors. Also note that there is an unused bond pad in the examples (on the upper left side) that could be used as an alternative site for source kelvin bonding. It could also be used as a bonding site for on-chip sensors like temperature, current, and the like. Additional bonding pads would be configured to match the specific needs of that particular device.

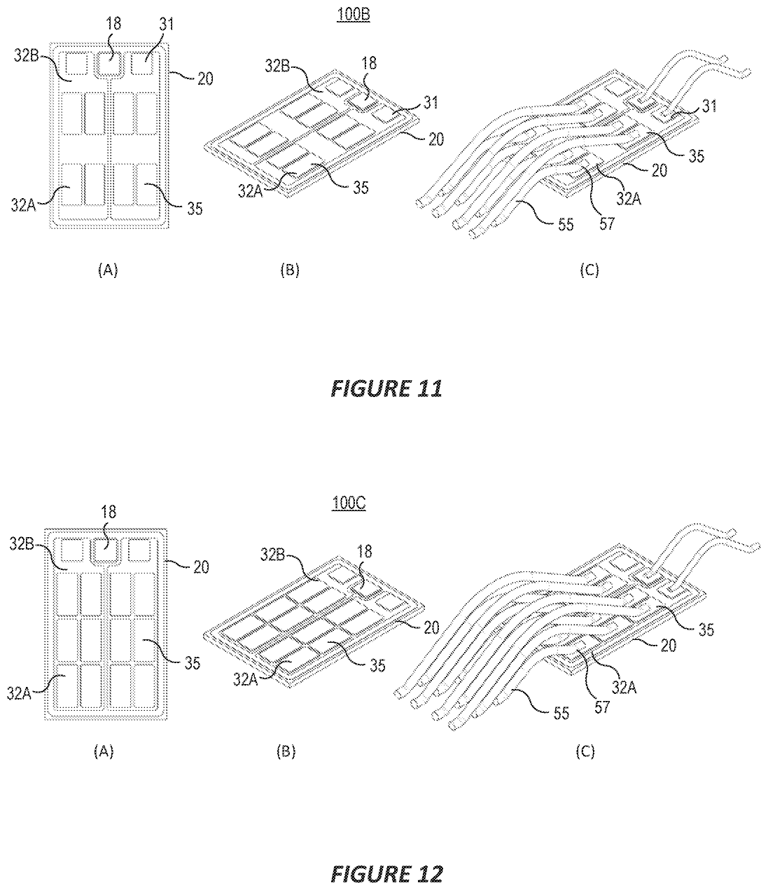

FIG. 11 depicts an example topside pattern for wire bonding in a device 100B including a plurality of bond pads 35 on a thin metal layer 32B that provides source contacts for the device 100B. The bond pads 35 may be square, rectangular or any other shape as desired to provide sufficient room for a wire bond foot 57 of a wire bond 55 that is connected to the bond pad 35. In the device 100B, the bond pads 35 are formed in pairs and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and directly away from the gate pad 18.

In some cases, as much of the device topside area as possible is used for bonding. FIG. 12 depicts an example ‘fully loaded’ topside pattern for a device 100C with a dense arrangement of bond pads 35. The shapes of the bond pads 35 may be square or rectangular to provide sufficient room for the wire bond foot 57.

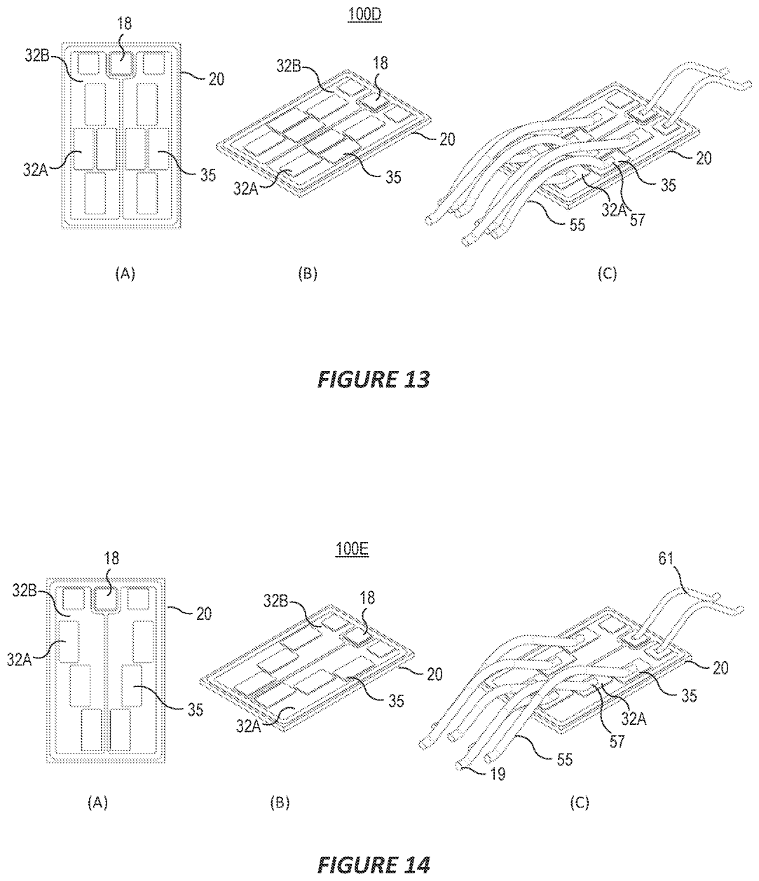

In some cases, the pads could be staggered or not in-line. This could be used to match a specific bonding pattern, or to specifically address a warpage or stress issue, such as removing thick metal from the corners. FIG. 13 depicts a device 100D having a example staggered topside pattern of bond pads 35. The shapes of the bond pads 35 may be square or rectangular to provide sufficient room for the wire bond foot.

Another staggered pattern is depicted in FIG. 14 where the bond pads 35 of a device 100E are staggered in a diagonal line such that wire bonds 55 are not stacked. This could find use for wire bonding processes with less capability to form precise loop heights.

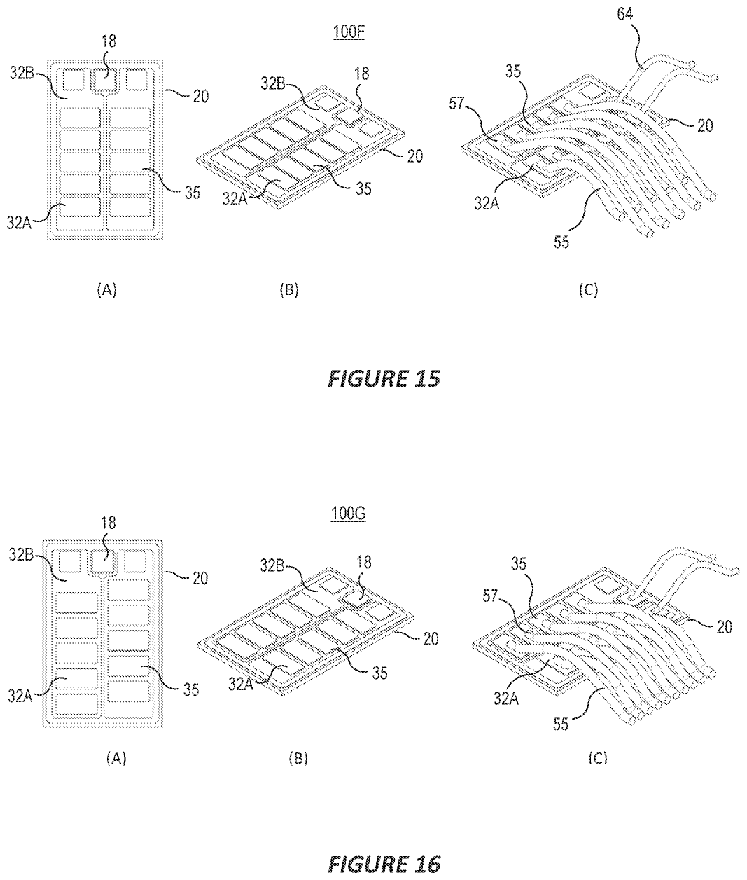

In many package types, the gate wire bonds 64 (i.e., those formed to the gate contact and that carry a signal) are formed in one direction, and the source wire bonds 55 (i.e., those formed to a source contact and that carry power) are formed in another direction. Often, they are orthogonal to each other. In other cases, they are bonded off in arbitrary angles. The size and location of the thick square or rectangular pads can be arranged to accommodate these bond angles. An example pattern for orthogonal bonding for a device 100F is illustrated in FIG. 15. In particular, in the device 100F, the source wire bonds 55 are formed in an orthogonal direction relative to the gate wire bond 64. The rectangular bond pads 35 are arranged so that the source wire bonds 55 are parallel to the long sides of the bond pads 35.

Staggered angled or orthogonal patterns may also find use as shown in FIG. 16, which illustrates a device 100G. Here, the bonds are staggered on device such that the loop height of each bond may be the same. That is, the bond pads 35 are arranged so that no source wire bond 55 must extend over or across another source wire bond 55. This arrangement may be useful in packages where the height is limited, or the inductance of the wire bonds is paramount.

The bond pads 35 may typically be sized to match the bond foot at the desired bonding angle.

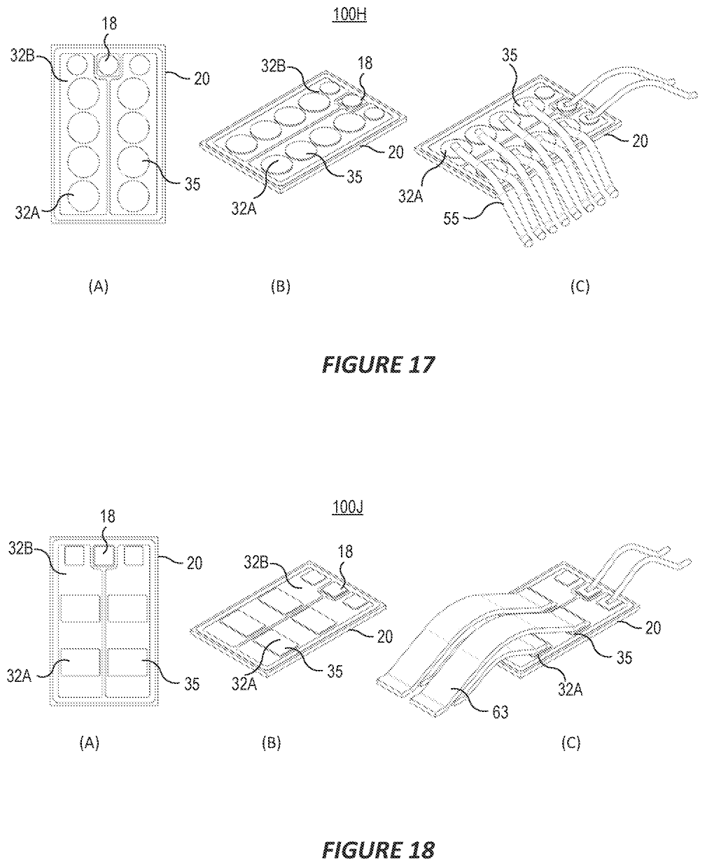

In some embodiments, the pads bond pads 35 may have a shape that is non-rectangular. For example, the bond pads 35 may be circular in shape so that bonding at any angle would be possible, such as illustrated in the device 100H FIG. 17. Circular features, in particular, may impart less stress to the substrate, thereby reducing warpage.

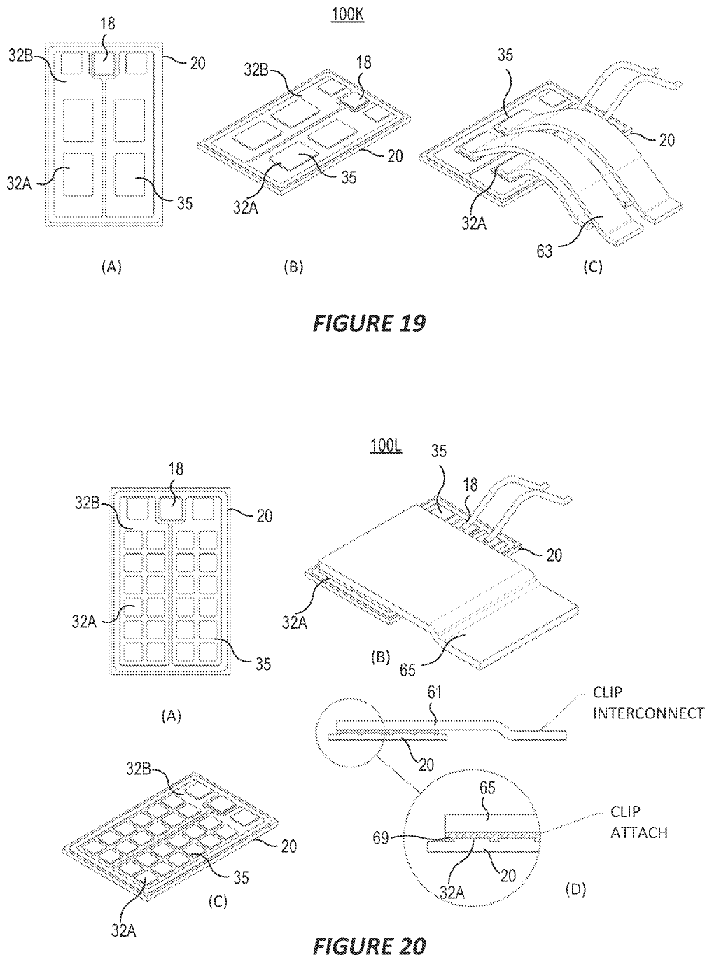

Selective metallization is also highly compatible with ribbon bonding. With ribbons, a rectangular cross section is used for the interconnect instead of a circular wire. This significantly enhances the ampacity and ruggedness of the bond. Examples for in-line and orthogonal bonding are shown in FIG. 18 and FIG. 19. For example, FIG. 18 illustrates a device 100J in which ribbon connections 63 are made to the bond pads 35. FIG. 18 illustrates a device 100K in which ribbon connections 63 are made to the bond pads 35 and extend in a direction that is orthogonal to the direction of the wire bond to the gate contact pad 18.

Note that a circular cross section may be used for the gate signal bonds to the gate pads 18, as pictured, since they are not carrying high currents. They may also be square or rectangular in cross section, however, in some applications where the robustness of that shape of wire is needed.

Topside enhancements are not limited to wire and ribbon interconnects. For example, using a three-dimensional structure clip attach structure may also improve the reliability and ruggedness of a metallurgical bond (solder, sinter, etc.) or an adhesive bond (epoxy, etc.). Here, the three-dimensional structure acts as an anchoring feature. The three-dimensional structure adds significant strength to the attach in comparison to two flat surfaces bonded together. An example surface intended to provide structure to enhance soldering is shown in FIG. 20, which illustrates a clip interconnect 61 that is soldered to the topside metal layer 32 that includes a plurality of bond pads 35 on a thin metal layer 32B. The clip interconnect 61 is connected to the topside metal layer 32 via a solder connection 69.

The specific implementation of an enhancing surface for a clip attach will depend on the size, layout, and aspect ratio of the device and the design of the clip. A waffled pattern, as shown in FIG. 20, could be used. Other patterns such as stripes, dots, hatches, and the like could also find usage in some embodiments.

A clip interconnect 61 may also be used for a flip chip or double-sided package. In this application, the thick metal would act as a physical spacer to provide sufficient room for encapsulation or underfill to cover critical voltage blocking regions such as the edge termination.

FIGS. 27, 28 and 29 illustrate embodiments in which the topside metallization includes diagonalized bond pad arrangements. Such arrangements may impart lower stress to the underlying semiconductor structure as compared to the use of only orthogonal bond pads.

In particular, FIG. 27 depicts an example topside pattern for wire bonding in a device 100P including a plurality of bond pads 35 on a thin metal layer 32B that provides source contacts for the device 100P. The bond pads 35 may be square, rectangular or any other shape as desired to provide sufficient room for a wire bond foot 57 of a wire bond 55 that is connected to the bond pad 35. In the device 100B, the bond pads 35 are formed as diagonal regions on the semiconductor die 20 and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and away from center of the die 20 at oblique angles. Additional triangular bonding regions 35T may also be provided, for example, for source kelvin connections.

FIG. 28 depicts an example topside pattern for wire bonding in a device 100Q including a plurality of bond pads 35 on a thin metal layer 32B that provides source contacts for the device 100Q. The bond pads 35 may be square, rectangular or any other shape as desired to provide sufficient room for a wire bond foot 57 of a wire bond 55 that is connected to the bond pad 35. In the device 100N, the bond pads 35 are formed as diagonal cross-shaped regions on the semiconductor die 20 and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and away from center of the die 20 at oblique angles. Additional triangular bonding regions 35T may also be provided, for example, for source kelvin connections.

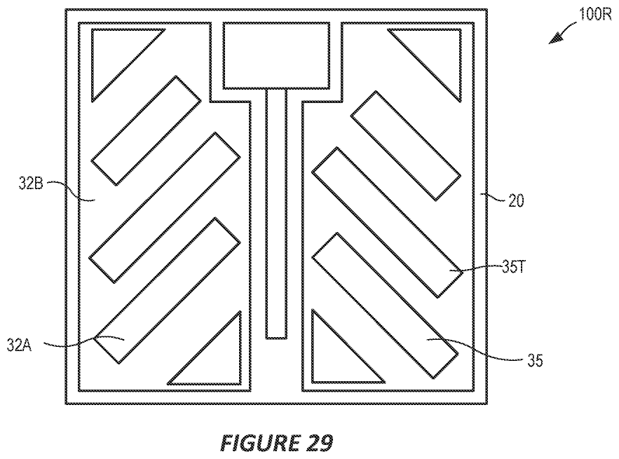

FIG. 29 depicts an example topside pattern for wire bonding in a device 100R including a plurality of bond pads 35 on a thin metal layer 32B that provides source contacts for the device 100R. The bond pads 35 may be square, rectangular or any other shape as desired to provide sufficient room for a wire bond foot 57 of a wire bond 55 that is connected to the bond pad 35. In the device 100N, the bond pads 35 are formed as diagonal regions on the semiconductor die 20 in a chevron pattern and arranged to allow individual wire bond connections 55 thereto. The bond pads 35 have a rectangular shape with an aspect ratio of long side to short side that is selected to permit the bond pads 35 to receive a wire bond connection 55 that extends in a direction parallel to the long side of the bond pad 35 and away from center of the die 20 at oblique angles. Additional triangular bonding regions 35T may also be provided, for example, for source kelvin connections.

### Backside Embodiments

There are many implementations of backside metallization using a selective metal approach according to some embodiments. The specific approach could be tailored to accommodate a number of factors, including one or more of device size, device aspect ratio, device shape, pad size, interconnection method, interconnection material, bonding direction, bonding pattern, package features and/or product application.

Example backside features are described in the following for a reference device. These may be used by themselves or in combination with topside features depending on many of the factors listed above. Note that specific implementation is not limited to these examples, and ultimately is driven by product and application factors.

Thicker metal on the device backside can provide benefits such as thermal buffering, added mechanical robustness, and compatibility with some attach methods (diffusion bonding, for example). Similar to the topside metallization, warpage issues limit what is practical. A selective approach is an attractive solution, as the metal plane can be broken up such that the copper fields have room to expand without creating warpage in the wafer.

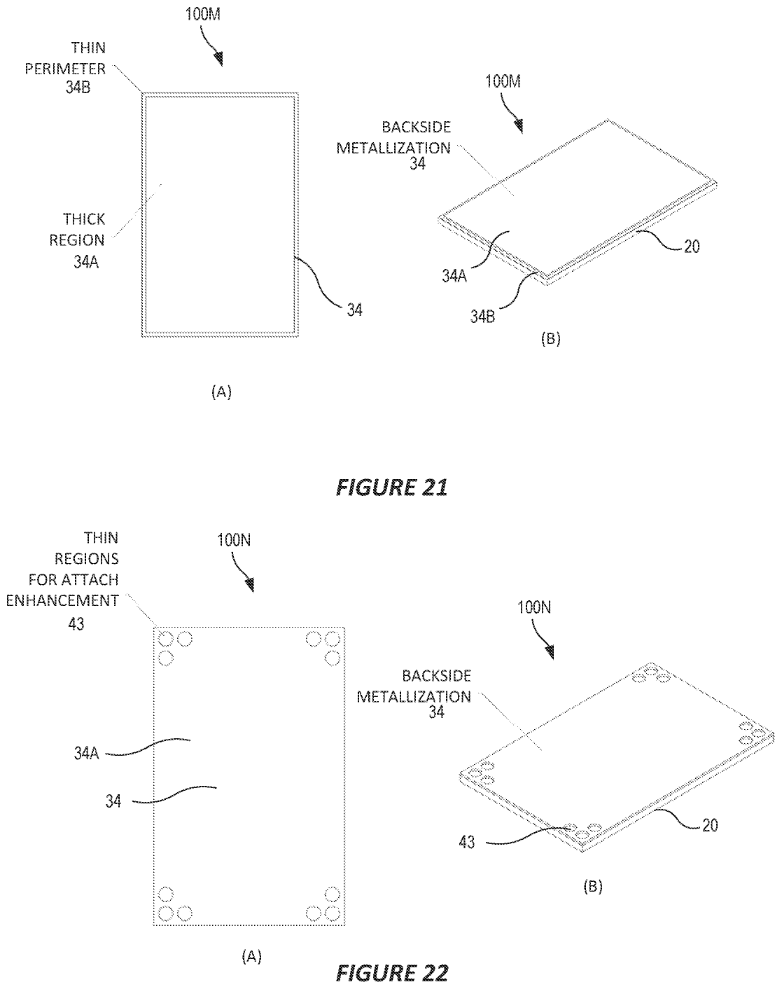

FIG. 21 illustrates an example of a device 100M in which a metal layer 34 includes a thick portion 34A (e.g., of copper) is provided over most of the device backside. The metal layer 34 includes a thin portion 34B is formed as a perimeter around the outside of the thick portion 34A. Here, each die 20 would have its own thick region, while the entire wafer backside would be broken up such that there is not a single large field of thick metal. Note that in some cases, the thick portion 34A of the metal layer 34 could fill the entire backside, while the thin portions 34B are in the dicing streets between devices.

In some embodiments, the thick portion 44A and the thin portion 34B of the metal layer 34 are provided by separate layers that are formed from different metals. For example, the thick portion 34B may be copper, while the thin portion may be aluminum copper.

Additionally, providing thicker metal on both sides of the wafer can manifest in a stress balance such that the warpage induced by the patterns could ‘equal out’, resulting in a net flattening effect on the final distorted shape.

The selective pattern could also be used as a means to enhance the reliability of the device attach. For example, thin regions in the corner could be used to increase the surface area of a solder bond, as it is known that device corners may be a weak spot at which metal delamination may occur. As shown in FIG. 22, the thin portion 34B comprises recessed features 43 that are placed in the corners of the thick metal layer 34A of a backside metallization 34 of a device 100N. During processing, molten solder would flow into the recessed features 43, filling them entirely. This may anchor and strengthen the solder bond in the region where delamination is most likely to occur. Similar benefits could be envisioned for other attach materials and processes, such as sintering, diffusion bonding, adhesive bonding, and the like. The recessed features 43 may be circular as shown in FIG. 22, or may have any other peripheral shape (e.g., square, rectangular, hexagonal, etc.).

Recessed features could also be used as a manner of bond line control. In this case, pressure during the attach process could ‘flatten out’ the bond line by pressing the thick regions directly against the power substrate.

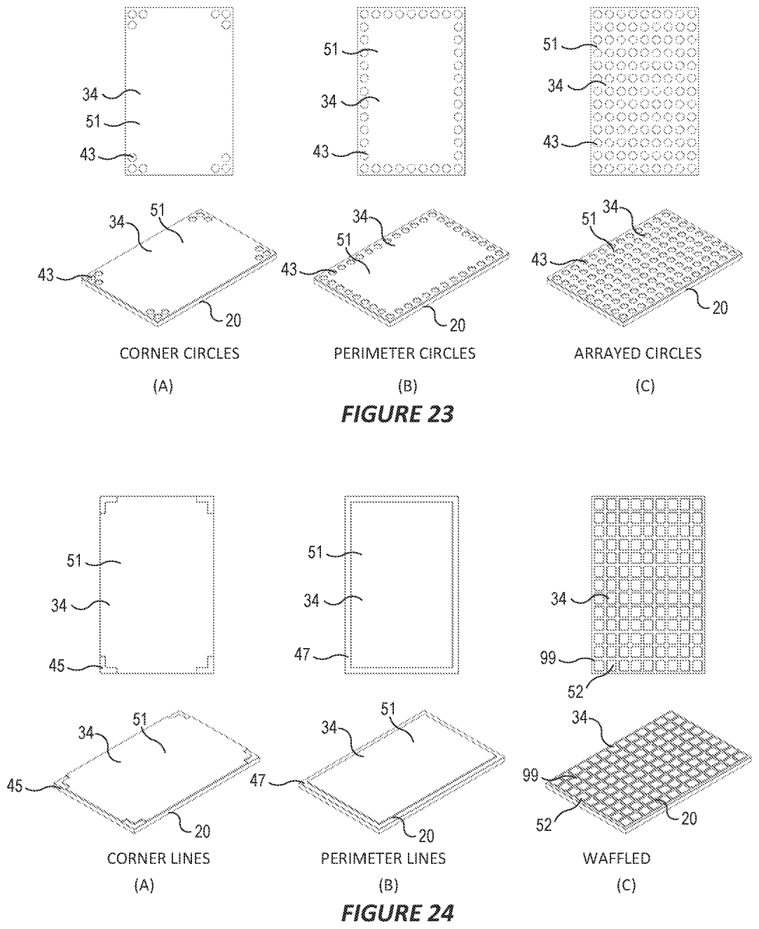

FIG. 23 shows backside enhancements of a device using thin circular features 43. The location and pattern can be driven by a number of factors. For example, FIG. 23(A) illustrates a device including three thin circular features 43 in each corner. FIG. 23(B) illustrates a device including thin circular features 43 along the sides. FIG. 23(C) illustrates a device including thin circular features 43 arranged in a two-dimensional array of rows and columns.

Thin corner and edge features add robustness in the attach layers where stress is the highest, while leaving the central area thick for optimal heat spreading/thermal performance. An arrayed approach could get the most rugged attach at the tradeoff of reduced thermals.

Thin circular features could potentially be of varying diameter. In this implementation, the diameter of the feature and the associated strengthening/anchoring geometry could vary based on the stress pattern of the device. For example, smaller diameter circles in the middle and larger diameter circles in the corners.

Linear features could also be beneficial, particular on the perimeter. FIG. 24 illustrates example linear corner, perimeter, and array features.

FIG. 24(A) illustrates a device including three recessed features 45 in each corner. A thick metal region 51 covers the center of the backside of the device. FIG. 24(B) illustrates a device including thin linear recessed features 47 along the perimeter of the die 20 around the thick metal region 51. FIG. 24(C) illustrates a device including thin linear recessed features 99 arranged in a two-dimensional array of rows and columns that define thick metal regions 52 therebetween. As shown in FIG. 24(C), in some embodiments, the backside metallization may include a metal layer on the back side semiconductor die, where the metal layer has a first thickness, and at least two discrete pads on the metal layer, wherein the at least two discrete pads have a second thickness that is larger than the first thickness.

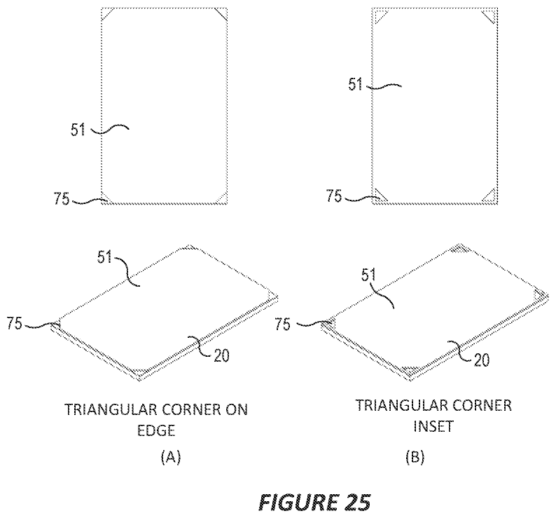

FIG. 25(A) illustrates a device including triangular recessed corner features 75 at the corners of the die 20. A thick metal region 51 covers the center of the backside of the device.

Depending on process and method, edge linear recessed features may have challenges in wafer dicing or device segmentation. In this case, the triangular recessed features 75 could be inset inside of the corners of the thick metal region 51 as shown in FIG. 25(B).

Many of the features described above can be used in combination. For example, the recessed circular features 43 shown in FIGS. 22 and 23 and/or the recessed corner features 45, 75 shown in FIGS. 24 and 25 may be using in combination with the thin perimeter metallization 34B shown in FIG. 21. Any other similar combination of features may be used depending on the needs of the application.

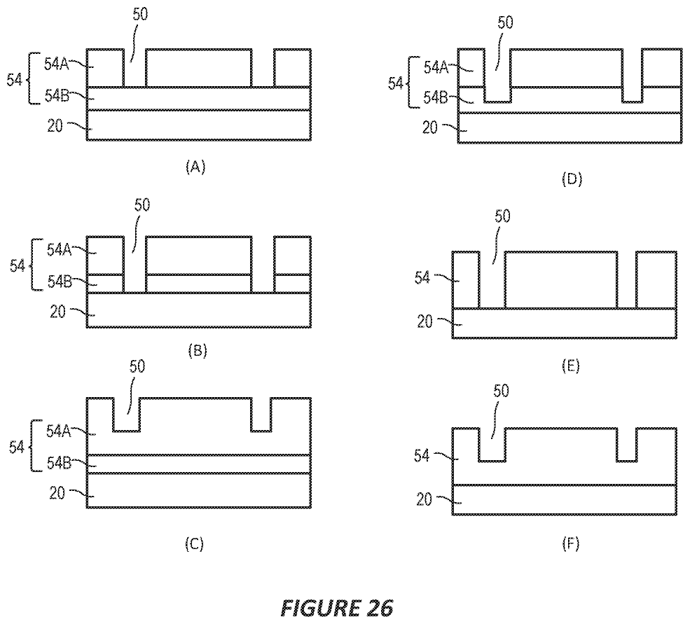

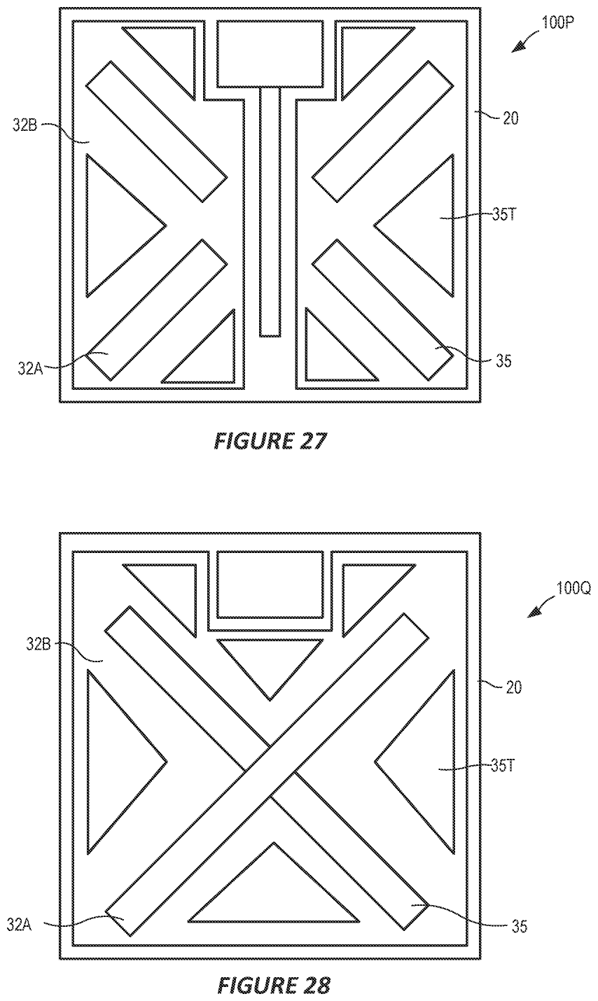

FIG. 26 illustrates configurations of metal layers and recessed features according to various embodiments. Each structure includes a plurality of recessed features 50, which may correspond to one or more of the recessed features 43, 45, 47, 75 described above in connection with FIGS. 21-25. For example, FIGS. 26(A), 26(B), 26(C) and 26(D) illustrate embodiments in which a backside metal layer 54 includes a first metal layer 54A and a second metal layer 54B on the semiconductor die 20, where the first metal layer 54A is on the second metal layer 54B and the second metal layer 54B is on the semiconductor die 20. The first metal layer 54A may correspond to the thick region 34A shown in FIG. 21 while the second metal layer 54B may correspond to the thin region 34B shown in FIG. 21.

As shown in FIGS. 26(A), 26(B), 26(C), and 26(D), the recessed features 50 may extend only through the first metal layer 54A (FIG. 26(A)), completely through the first metal layer 54A and the second metal layer 54B (FIG. 26(B)), partially through the first metal layer 54A (FIG. 26(C)), or completely through the first metal layer 54A and partially through the second metal layer 54B (FIG. 26(D)).

FIGS. 26(E) and 26(F) illustrate embodiments in which a backside metal layer 54 includes a single metal layer. As shown in FIGS. 26(E) and 26(F), the recessed features 50 may extend completely through the metal layer 54 (FIG. 26(E)) or partially through the metal layer 54 (FIG. 26(F)).

Moreover, in any of the described embodiments, a single device may include one or more recessed features 50 that extend completely or partially through a given layer 54, 54A, 54B and one or more other recessed features 50 that do not extend completely or partially through the given layer 54, 54A, 54B.

While the above-described power semiconductor devices and the other devices described herein are shown as being silicon carbide-based semiconductor devices, it will be appreciated that embodiments of the present inventive concepts are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The inventive concepts have been described above with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present inventive concepts.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the inventive concepts.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present inventive concepts may include additional and/or intervening layers, structures, or elements, and/or particular layers, structures, or elements may be deleted. Although a few exemplary embodiments of the inventive concepts have been described, those skilled in the art will readily appreciate that many modifications are possible in the exemplary embodiments without materially departing from the novel teachings and advantages of the inventive concepts. Accordingly, all such modifications are intended to be included within the scope of the inventive concepts as defined in the claims. Therefore, it is to be understood that the foregoing is illustrative of the present inventive concepts and is not to be construed as limited to the specific embodiments disclosed, and that modifications to the disclosed embodiments, as well as other embodiments, are intended to be included within the scope of the appended claims. The inventive concepts are defined by the following claims, with equivalents of the claims to be included therein.

1. A semiconductor device, comprising:
a semiconductor die (20); and
a topside metallization (32A, 32B) on a first side of the semiconductor die;
wherein the topside metallization comprises a metal layer (32B) on the semiconductor die, the metal layer having a first thickness, and at least two discrete bond pads (32A) on the metal layer, wherein the at least two discrete bond pads have a second thickness that is larger than the first thickness.

2. The semiconductor device of claim 1, wherein semiconductor device further comprising at least two wires bonded to respective ones of the discrete bond pads.

3. The semiconductor device of claim 1, wherein the at least two bond pads comprise at least two source bond pads and a kelvin bond pad.

4. The semiconductor device of claim 3, wherein the kelvin bond pad has a different surface area than the source bond pads.

5. The semiconductor device of claim 1, wherein the at least two bond pads comprise emitter or anode pads.

6. The semiconductor device of claim 1, wherein the discrete bond pads are oriented in a staggered or offset pattern on the metal layer.

7. The semiconductor device of claim 1, wherein the discrete bond pads are oriented on the metal layer in a pattern of rows and columns.

8. The semiconductor device of claim 1, wherein the discrete bond pads are oriented on the metal layer in a pattern of diagonals, crosses and/or in a chevron pattern.

9. The semiconductor device of claim 1, wherein the discrete bond pads have a rectangular peripheral shape.

10. The semiconductor device of claim 1, wherein the discrete bond pads have a circular, oval or octagonal peripheral shape.

11. The semiconductor device of claim 1, comprising a clip interconnect or ribbon connection connected to the at least two discrete bond pads.

12. The semiconductor device of claim 1, wherein the metal layer comprises copper.

13. The semiconductor device of claim 1, wherein the at least two discrete bond pads comprise copper.

14. The semiconductor device of claim 1, wherein the at least two discrete bond pads are inset from edges of the metal layer.

15. The semiconductor device of claim 1, wherein the metal layer comprises a barrier layer and a capping layer, wherein the barrier layer is between the semiconductor die and the capping layer, and wherein an outer edge of the capping layer is inset from an outer edge of the barrier layer.

16. The semiconductor device of claim 1, wherein the metal layer comprises a material that has a mechanical strength that is about the same as a material of the discrete bond pads.

17. The semiconductor device of claim 16, wherein the metal layer and the discrete bond pads comprise the same material.

18. The semiconductor device of claim 1, wherein the discrete bond pads comprise a material that has a mechanical strength that is great enough to support formation of wirebonds thereto.

19. The semiconductor device of claim 1, wherein the at least two discrete bond pads are electrically connected to source, emitter, anode and/or gate contacts of the semiconductor device.

20. The semiconductor device of claim 1, wherein a total surface area of the discrete bond pads is greater than a surface area of the metal layer.

21. The semiconductor device of claim 1, wherein the metal layer is non-planar.

22. The semiconductor device of claim 1, further comprising:
a backside metallization on a second side of the semiconductor die opposite the first side;
wherein the backside metallization comprises a thin metal layer and a thick metal layer on the thin metal layer, wherein at least a portion of the second side of the semiconductor die is free of the thick metal layer so that at least a portion of the thin metal layer is exposed opposite the semiconductor die.

23. The semiconductor device of claim 1, wherein the at least two bond pads are arranged to reduce stress that would be otherwise be imparted to the semiconductor die if the at least two bond pads were formed as a single unitary bond pad.

24. A semiconductor device, comprising:
a semiconductor die (20) having a first side and a second side opposite the first side;
at least one bond pad on the first side of the semiconductor die; and
a backside metallization (34A, 34B) on the second side of the semiconductor die;
wherein the backside metallization comprises a metal layer having a first portion having a first thickness and a second portion having a second thickness that is smaller than the first thickness.

25. The semiconductor device of claim 24, wherein the second portion of the metal layer comprises a peripheral region surrounding the first portion.

26. The semiconductor device of claim 24, wherein the second portion of the metal layer comprises at least two of attachment regions within a periphery of the first portion of the metal layer.

27. The semiconductor device of claim 26, wherein the attachment regions within the periphery of the first portion of the metal layer comprise at least two regions near corners of the first portion of the metal layer.

28. The semiconductor device of claim 26, wherein the attachment regions within the periphery of the first portion of the metal layer comprise at least two regions near edges of the first portion of the metal layer.

29. The semiconductor device of claim 26, wherein the attachment regions within the periphery of the first portion of the metal layer comprise at least two regions arranged in rows and columns.

30. The semiconductor device of claim 26, wherein the attachment regions within the periphery of the first portion of the metal layer comprise at least two linear regions.

31. The semiconductor device of claim 26, wherein the attachment regions comprise regions having a peripheral shape that is circular, square, triangular, rectangular, L-shaped, linear, octagonal or irregular.

32. The semiconductor device of claim 24, further comprising:
a topside metallization on the first side of the semiconductor die;
wherein the topside metallization comprises a first metal layer on the semiconductor die, the first metal layer having a first thickness, and at least two discrete bond pads on the metal layer, wherein the at least two discrete bond pads have a second thickness that is larger than the first thickness.
